(19) United States
(12) Patent Application Publication
(10) Pub. No.: US 2024/0357886 A1
(43) Pub. Date: Oct. 24, 2024

(54) DISPLAY DEVICE

(71) Applicant: Samsung Display Co., LTD., Yongin-si (KR)

(72) Inventors: Seung Min LEE, Yongin-si (KR); Dong Jo KIM, Yongin-si (KR); Hyun KIM, Yongin-si (KR); Seong Geun WON, Yongin-si (KR); Je Won YOO, Yongin-si (KR); Dan Bi CHOI, Yongin-si (KR); Souk June HWANG, Yongin-si (KR)

(73) Assignee: Samsung Display Co., LTD., Yongin-si (KR)

(21) Appl. No.: 18/532,692

(22) Filed: Dec. 7, 2023

(30) Foreign Application Priority Data
Apr. 24, 2023 (KR) 10-2023-0053505

(51) Int. Cl. H10K 59/131; H10K 59/127; H10K 77/10

(52) U.S. Cl. CPC H10K 59/131; H10K 59/127; H10K 77/111; H10K 2102/351

(57) ABSTRACT

A display device including a first substrate including a first area, a second area and a bending area between the first area and the second area; a display element layer disposed on the first area of the first substrate; multiple signal lines disposed on the bending area of the first substrate, the signal lines being spaced apart from one another in a first direction and electrically connected to the display element layer; and a bending protection layer disposed on the bending area of the first substrate and covering the signal lines, wherein the bending protection layer includes a first portion and a second portion, the first portion has an inclined surface, the second portion having an approximately flat surface, the second portion overlapping the signal lines including outermost signal lines, the first portion not overlapping the signal lines.

### CROSS-REFERENCE TO RELATED APPLICATIONS

his application claims priority under 35 U.S.C. § 119 from Korean Patent Application No. 10-2023-0053505 under 35 U.S.C. § 119 filed on Apr. 24, 2023 in the Korean Intellectual Property Office, the entire contents of which are incorporated herein by reference.

### BACKGROUND

### 1. Technical Field

The disclosure relates to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices may include an organic light-emitting display device including an organic light-emitting element, an inorganic light-emitting display device including an inorganic light-emitting element such as an inorganic semiconductor, and a micro-light-emitting display device including an ultra-small light-emitting element.

Recently, in order to widen a display area in which emission areas for displaying images may be arranged, non-display area (or a bezel area) other than the display area may be reduced. As the non-display area (or bezel area) may be reduced, the width of the voltage lines disposed in the non-display area (or bezel area) may be reduced. As a result, the resistance of the voltage lines increases, and heat may be generated in the voltage lines as electric current may be concentrated in a bottleneck of the voltage lines. Therefore, pixels adjacent to the voltage lines may deteriorate by the heat from the voltage lines.

### SUMMARY

Aspects of the disclosure provide a display device in which multiple signal lines may be disposed under a bending protection layer having a thickness in a range, which can prevent crack defects in the lines in case that the display device is bent.

It should be noted that objects of the disclosure may not be limited to the above-mentioned object; and other objects of the disclosure will be apparent to those skilled in the art from the following descriptions.

An embodiment of a display device may include a first substrate comprising a first area, a second area and a bending area between the first area and the second area; a display element layer disposed on the first area of the first substrate; multiple signal lines disposed on the bending area of the first substrate, the signal lines being spaced apart from one another in a first direction and being electrically connected to the display element layer; and a bending protection layer disposed on the bending area of the first substrate and covering the signal lines, wherein the bending protection layer includes a first portion that does not overlap the signal lines, the first portion having an inclined surface along the first direction; and a second portion that overlaps the signal lines, the second portion may extending to the first portion along the first direction, and the second portion may have an approximately flat surface, and wherein the signal lines include a first outermost signal line at an outermost location among the signal lines in the first direction, and the first outermost signal line overlaps the second portion of the bending protection layer.

The bending protection layer may further comprise a third portion disposed on an opposite side in the first direction from the first portion, the second portion being disposed between the first portion and the third portion, the third portion including an inclined surface, The signal lines may further comprises a second outermost signal line at an outermost location among the signal lines in the first direction and disposed at an opposite side from the first outermost signal line, and the second outermost signal line may overlap the second portion.

The inclined surface of the first portion of the bending protection layer, the approximately flat surface of the second portion and the inclined surface of the third portion may be contiguous, and a thickness of the second portion of the bending protection layer in a direction perpendicular to the first direction may be greater than thicknesses of the first and third portions of the bending protection layer.

The first outermost signal line and the second outermost signal line may overlap neither the first portion nor the third portion of the bending protection layer.

The thickness of the second portion of the bending protection layer may be greater than about 90 μm and equal to or less than about 120 μm.

The inclined surface of the first portion and the inclined surface of the third portion of the bending protection layer may be inclined toward respective edges of the first substrate disposed adjacent thereto.

The thickness of the first portion and the thickness of the third portion of the bending protection layer may be greater than about 0 μm and equal to or less than about 90 μm.

Widths of the first portion and the third portion of the bending protection layer in the first direction may be equal to or greater than about 800 μm and equal to or less than about 1,000 μm.

The bending area of the first substrate may comprise an edge portion not overlapping the bending protection layer, the edge portion of the bending area of the first substrate may comprise edges of the first substrate at opposing sides in the first direction, and a width of the edge portion of the bending area of the first substrate in the first direction may be in a range from about 800 μm to about 1,000 μm.

A distance in the first direction from a nearest one of the respective edges of the first substrate to a side edge of the first outermost signal line may be equal to or greater than about 1,800 μm.

An embodiment of a display device further include a second substrate disposed on the first substrate, the first substrate being disposed between the display element layer and the second substrate, wherein the second substrate may further comprise a (2-1)-th substrate overlapping the first area of the first substrate; and a (2-2)-th substrate overlapping with the second area of the first substrate, and the bending protection layer may partially overlap the second substrate, and wherein the (2-1)-th substrate and the (2-2)-th substrate may be spaced apart from each other.

The second substrate may do not overlap the bending area.

A surface of the second substrate facing away from the first substrate may comprise inclined surfaces at opposing ends, and wherein at least one of the inclined surfaces may overlap the bending protection layer.

An embodiment of a display device includes a substrate comprising a first area, a second area and a bending area between the first area and the second area; a display element layer disposed on the first area of the substrate; multiple signal lines disposed on the bending area of the substrate, the signal lines may be spaced apart from one another in a first direction, and the signal lines may be electrically connected to the display element layer; and a bending protection layer disposed on the bending area of the substrate and covering the signal lines, wherein the signal lines may comprise a first outermost signal line at an outermost location in the first direction among the signal lines, and wherein the bending protection layer may include a first end that may be disposed between a first edge of the substrate and the first outermost signal line.

The signal lines may further comprise a second outermost signal line disposed at an outermost location in the first direction among the signal lines, the second outermost signal line may be disposed on an opposite side from the first outermost signal line, and wherein the bending protection layer includes a second end that may be disposed between a second edge of the substrate and the second outermost signal line.

A thickness of the bending protection layer overlapping the signal lines in a direction perpendicular to the first direction may be greater than about 90 μm and equal to or less than about 120 μm.

A distance between the first edge of the substrate and an edge of the first outermost signal line facing the first end of the bending protection layer, and a distance between the second edge of the substrate and an edge of the second outermost signal line facing the second end of the bending protection layer may be greater than about 1,800 μm.

A distance in the first direction from the first edge of the substrate to the first end of the bending protection layer may be in a range of about 800 μm to about 1,000 μm.

A distance in the first direction between the first end of the bending protection layer and the edge of the first outermost signal line facing the first end of the bending protection layer in the first direction, and a distance between the second end of the bending protection layer and the edge of the second outermost signal line facing the second end of the bending protection layer may be in a range of about 800 μm to about 1,000 μm.

The signal lines may not be disposed between the edges of the substrate and the ends of the bending protection layer.

According to the embodiments of the disclosure, multiple signal lines may be disposed under a bending protection layer having a thickness in a range in a display device, so that it may be possible to reduce bending stress applied to the signal lines in case that the display device is bent.

According to the embodiments of the disclosure, multiple signal lines may be disposed under a bending protection layer having a thickness in a range in a display device, so that it may be possible to prevent crack defects in the signal lines in case that the display device is bent.

It should be noted that effects of the disclosure may not be limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a plan view showing a display device according to an embodiment of the disclosure;

FIG. 2 is a perspective view showing the display device of FIG. 1 in case that the subsidiary area is bent;

FIG. 3 is a schematic cross-sectional view of the display device, taken along line X1-X1′ of FIG. 1;

FIG. 4 is a schematic cross-sectional view showing the display device of FIG. 3 in case that the subsidiary area is bent;

FIG. 5 is a plan view showing a display device before a circuit board may be attached thereto;

FIG. 6 is an enlarged plan view of area A of FIG. 5;

FIG. 7 is an enlarged plan view of area C of FIG. 5;

FIG. 8 is a schematic cross-sectional view of the bending area of the display device of FIG. 7, taken along line X3-X3′;

FIG. 9 is a schematic cross-sectional view of an outermost signal line of the display device, taken along line X5-X5′ of FIG. 7;

FIG. 10 is a schematic cross-sectional view of the outermost signal line of FIG. 9 in case that it is bent;

FIG. 11 is an enlarged plan view of area C of FIG. 5 as Comparative Example; and

FIG. 12 is a schematic cross-sectional view of the display device, taken along line X7-X7′ of FIG. 11.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing exemplary features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Hereinafter, embodiments of the disclosure will be described in detail with reference to the accompanying drawings.

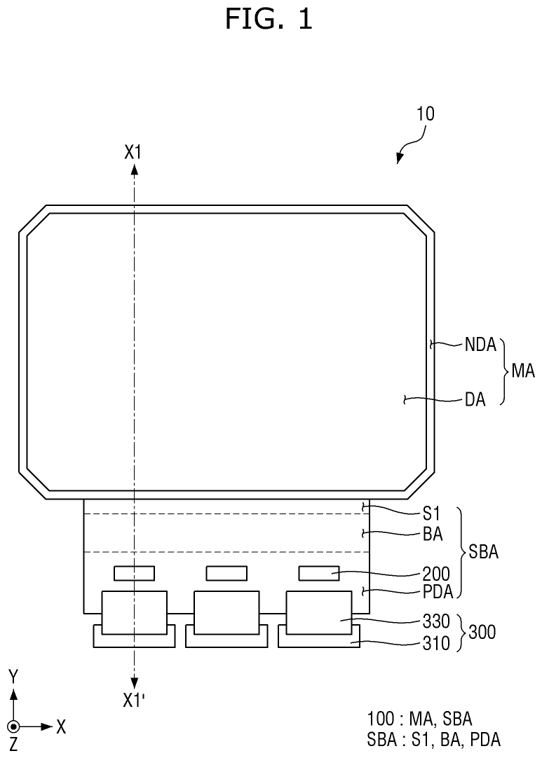

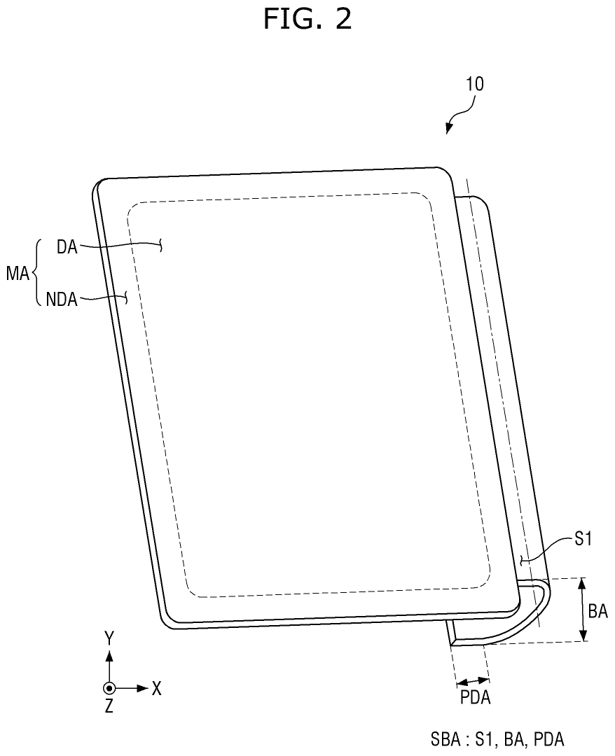

FIG. 1 is a plan view showing a display device according to an embodiment of the disclosure. FIG. 2 is a perspective view showing the display device of FIG. 1 in case that the display device may be bent.

Referring to FIGS. 1 to 2, a display device 10 may be for displaying moving images or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things (IoT).

The display device 10 may be a light-emitting display device such as an organic light-emitting display device using organic light-emitting diodes, an inorganic light-emitting display device including an inorganic semiconductor, and a micro light-emitting display device using micro or nano light-emitting diodes (micro LEDs or nano LEDs). In the following description, an organic light-emitting display device may be described as an example of the display device 10. It is, however, to be understood that the disclosure may not be limited thereto.

The display device 10 may include a display panel 100, a display driver circuit 200 and a circuit board 300.

The display panel 100 may be formed in a rectangular plane having longer sides in a first direction (x-axis direction) and shorter sides in a second direction (y-axis direction) intersecting the first direction (x-axis direction). Each of the corners where the longer side in the first direction (x-axis direction) meets the shorter side in the second direction (y-axis direction) may be rounded with a curvature or may be a right angle. The shape of the display panel 100 in case that viewed from the top is not limited to a quadrangular shape, but may be formed in a different polygonal shape, a circular shape, or an elliptical shape. The display panel 100 may be formed approximately flat, but may not be limited thereto. For example, the display panel 100 may be formed at left and right ends, and may include a curved portion having a constant curvature or a varying curvature. In addition, the display panel 100 may be flexible so that it can be curved, bent, folded or rolled.

The display panel 100 may include the main area MA and a subsidiary area SBA.

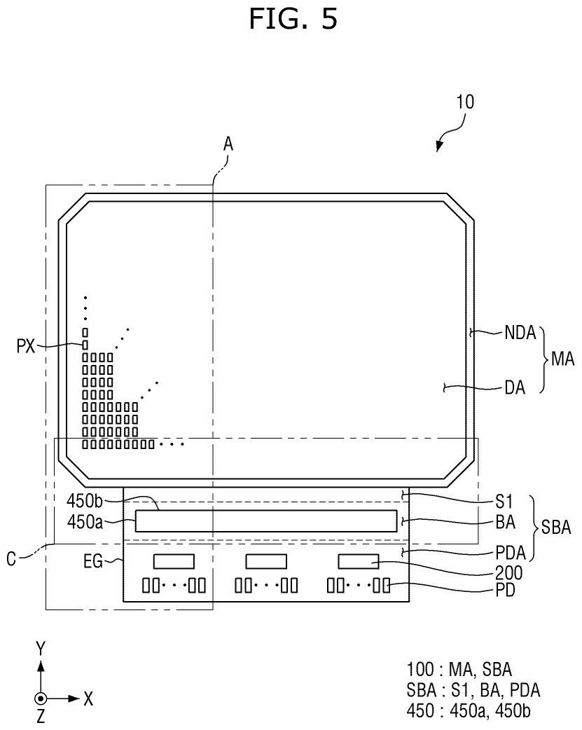

The main area MA may include a display area DA where images may be displayed, and a non-display area NDA around the display area DA. The display area DA may occupy most of the main area MA. The display area DA may be disposed at the center of the main area MA. In the display area DA, pixels PX (see FIG. 5) each including multiple emission areas may be disposed to display images.

The non-display area NDA may be disposed adjacent to the display area DA. The non-display area NDA may be disposed on the outer side of the display area DA. The non-display area NDA may surround the display area DA. The non-display area NDA may be defined as the border of the display panel 100.

The subsidiary area SBA may protrude from one side of the main area MA in the second direction (y-axis direction). The length of the subsidiary area SBA in the second direction (y-axis direction) may be smaller than the length of the main area MA in the second direction (y-axis direction). Although the length of the subsidiary area SBA in the first direction (x-axis direction) may be smaller than the length of the main area MA in the first direction (x-axis direction) in the example shown in FIG. 1, the disclosure may not be limited thereto. For example, the length of the subsidiary area SBA in the first direction (x-axis direction) may be substantially equal to the length of the main area MA in the first direction (x-axis direction).

The subsidiary area SBA may include a first subsidiary area S1, a bending area BA, and a pad area PDA.

The first subsidiary area S1 may protrude from one side of the main area MA in the second direction (y-axis direction). One side of the first subsidiary area S1 may be in contact with the non-display area NDA of the main area MA, and the opposite side of the first subsidiary area S1 may be in contact with the bending area BA.

The bending area BA may be bendable and may be disposed between the first subsidiary area S1 and the pad area PDA.

Referring to FIG. 2, the subsidiary area SBA may be bent by the bending area BA. The bent subsidiary area SBA may be disposed on the rear side of the display panel 100. In case that this happens, the pad area PDA of the subsidiary area SBA may overlap the main area MA in the third direction (z-axis direction).

In the pad area PDA, display pads PD (see FIG. 5) and the display driver circuit 200 may be disposed.

The display driver circuit 200 may generate signals and voltages for driving the display panel 100. The display driver circuit 200 may be implemented as an integrated circuit (IC) and may be attached to the display panel 100 by a chip on glass (COG) technique, a chip on plastic (COP) technique, or an ultrasonic bonding technique. It is, however, to be understood that the disclosure may not be limited thereto. For example, the display driver circuit 200 may be attached on the circuit board 300 by the chip-on-film (COF) technique.

The circuit board 300 may be attached to one end of the subsidiary area SBA of the display panel 100. Accordingly, the circuit board 300 may be electrically connected to the display panel 100 and to the display driver circuit 200. The display panel 100 and the display driver circuit 200 may receive digital video data, timing signals, and driving voltages through the circuit board 300. The circuit board 300 may include main circuit boards 310 and flexible circuit boards 330.

The main circuit boards 310 may further include multiple electronic components. The electronic components may be electrically connected through circuit lines. The main circuit boards 310 may be electrically connected to the display driver circuit 200 through the flexible circuit boards 330.

The flexible circuit boards 330 may extend to an end of the display panel 100 to connect the main circuit boards 310 with the display driver circuit 200. The flexible circuit boards 330 may be disposed on display pads PD (see FIG. 5) disposed at one edge of the display panel 100. The flexible circuit boards 330 may be attached to the display pads PD using a conductive adhesive member such as an anisotropic conductive film and an anisotropic conductive adhesive. Accordingly, the circuit boards 300 may be electrically connected to signal lines of the display panel 100.

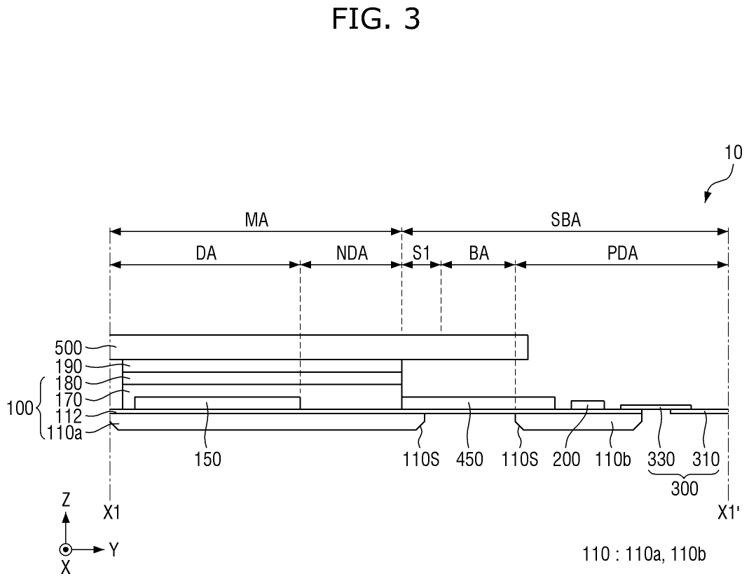

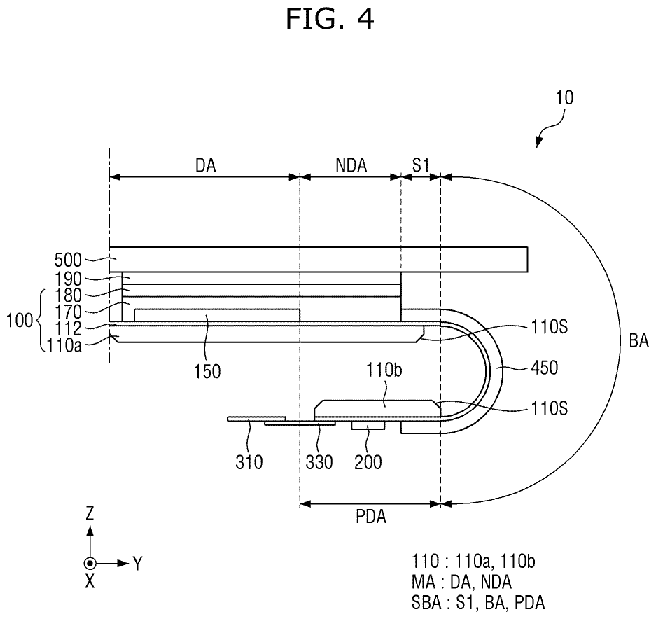

FIG. 3 is a schematic cross-sectional view of the display device, taken along line X1-X1′ of FIG. 1. FIG. 4 is a schematic cross-sectional view showing the subsidiary area SBA of the display device 10 of FIG. 3 in case that the display device 10 is bent.

Referring to FIGS. 3 and 4, the display device 10 according to the embodiment may include a display panel 100, a polarizing film 190, and a cover window 500. In some embodiments, the display panel 100 may include a first substrate 110, a second substrate 112, a display element layer 150, a thin-film encapsulation layer 170, a touch sensor layer 180, and a bending protection layer 450.

The first substrate 110 may be made of a light-transmitting material. In some embodiments, the first substrate 110 may be a glass substrate or a plastic substrate.

In some embodiments, the first substrate 110 may be partially etched to form the bending area BA and to support the second substrate 112. Accordingly, the first substrate 110 may be divided into a first portion 110a and a second portion 110b which may be spaced apart from each other. In some embodiments, the first portion 110a and the second portion 110b of the first substrate 110 undergo an etching process and accordingly may include inclined surfaces 110S at both (or opposing) ends of the bottom surface in the first direction (x-axis direction) that may not be in contact with (i.e., may face away from) the second substrate 112. In other words, it may be determined that the first substrate 110 has undergone an etching process if the inclined surfaces 110S are formed at both ends of the bottom surface of the first substrate 110, the bottom surface of the first substrate 110 may be a surface opposite from the surface of the first substrate 110 in contact with the second substrate 112.

In some embodiments, the first portion 110a of the first substrate 110 may overlap the main area MA and the first subsidiary area S1 of the subsidiary area SBA, and the second portion 110b of the first substrate 110 may overlap the pad area PDA of the subsidiary area SBA.

Referring to FIG. 4, in case that the subsidiary area SBA is bent, the first portion 110a of the first substrate 110 may overlap the display area DA of the main area MA, the first subsidiary area S1 of the subsidiary area SBA and the pad area PDA, and the second portion 110b of the first substrate 110 may overlap the non-display area NDA of the main area MA, the first subsidiary area S1 of the subsidiary area SBA, and the pad area PDA.

The second substrate 112 may be made of an insulating material such as a polymer resin. For example, the second substrate 112 may include polyimide (PI). The second substrate 112 may be a flexible substrate that can be bent, folded, or rolled.

The display element layer 150 may be disposed on the second substrate 112. The display element layer 150 may be a layer that displays images. The display element layer 150 may include an emissive layer EL for emitting light and a pixel-defining layer 155.

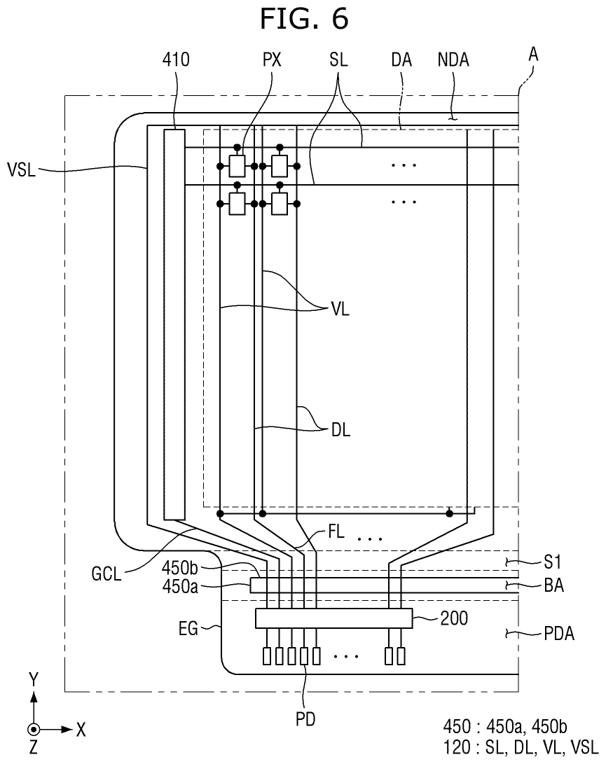

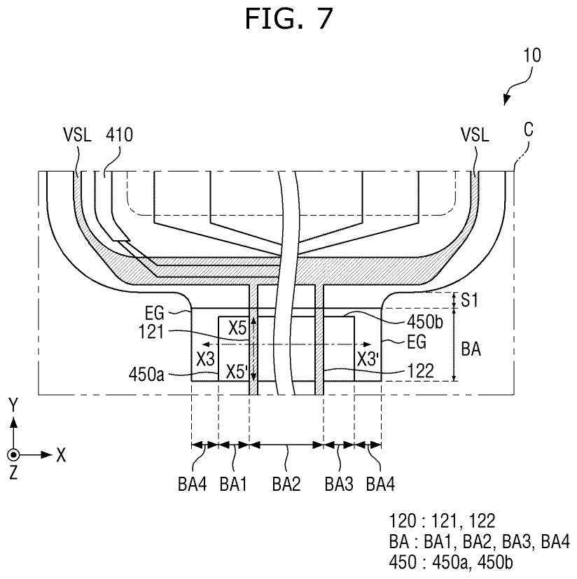

In the display area DA where the display element layer 150 may be disposed, multiple signal lines 120 (see FIG. 7) may be disposed so that the emission areas can emit light. The signal lines 120 may include scan lines, data lines, voltage lines, etc. In addition, in the non-display area NDA around the display element layer 150, a scan driving controller 410 outputting scan signals to the scan lines SL, fan-out lines FL connecting the data lines DL with the display driver circuit 200 (see FIG. 6), etc. may be disposed.

The thin-film encapsulation layer 170 may be disposed on the display element layer 150. The thin-film encapsulation layer 170 may include at least one inorganic film to prevent permeation of oxygen or moisture into the display element layer 150. The thin-film encapsulation layer 170 may also include at least one organic film to protect the display element layer 150 from particles such as dust.

The touch sensor layer 180 may be disposed on the thin-film encapsulation layer 170. The touch sensor layer 180 may include sensor electrodes. The touch sensor layer 180 may sense a user's touch using sensor electrodes.

The polarizing film 190 may be disposed on the display panel 100 in order to reduce reflection of external light. The polarizing film 190 may include a first base member, a linear polarizer, a retardation film such as a λ/4 (quarter-wave) plate, and a second base member. The first base member, the retardation film, the linear polarizer and the second base member of the polarizing film 190 may be sequentially stacked on the display panel 100.

The cover window 500 may be disposed on the polarizing film 190. The cover window 500 may be attached onto the polarizing film 190 by a transparent adhesive member such as an optically clear adhesive (OCA) film.

FIG. 5 is a plan view showing the display device 10 before the circuit board 300 is attached.

Referring to FIG. 5, multiple pixels PX may be disposed in the display area DA. The pixels PX may be electrically connected to the signal lines 120, respectively.

Multiple display pads PD may be disposed at an edge of the subsidiary area SBA. The display pads DP may be electrically connected to a graphic system through the circuit board 300. The display pads DP may be electrically connected to the circuit board 300 to receive digital video data and may supply the digital video data to the display driver circuit 200.

The display pads PD may be electrically connected to the signal lines 120 such as data lines DL, voltage lines VL, and scan lines SL electrically connected to the pixels PX disposed in the display area DA. As described above, the display panel 100 may extend to the flexible circuit boards 330 through the display pads PD, and thus electrical signals provided from the main circuit boards 310 may be transmitted to the pixels PX.

According to some embodiments of the disclosure, the bending protection layer 450 may be disposed on the subsidiary area SBA of the display device 10. Although the bending protection layer 450 may be disposed on the bending area BA in the example shown in FIG. 5, the disclosure may not be limited thereto. The bending protection layer 450 may be further disposed in the first subsidiary area S1 and in the pad area PDA.

In some embodiments, the bending protection layer 450 may include a shorter surface 450a that extends in the second direction (y-axis direction) and a longer surface 450b that extends in the first direction (x-axis direction). The shorter surface 450a of the bending protection layer 450 may be parallel to the direction of the shorter sides of the display device 10, and the longer surface 450b of the bending protection layer 450 may be parallel to the direction of the longer sides of the display device 10.

In some embodiments, the bending protection layer 450 may be spaced apart from both edges EG of second substrate 112 in the first direction (x-axis direction). Therefore, the bending protection layer 450 may not be disposed between the shorter surface 450a of the bending protection layer 450 and the edge EG of the second substrate 112.

The bending protection layer 450 may cover the bending area BA and may be bent together with the bending area BA. The bending protection layer 450 can protect the bending area BA from external impact.

FIG. 6 is an enlarged plan view of area A of FIG. 5.

Referring to FIG. 6, the pixels PX may be electrically connected to the signal lines 120. For example, each of the pixels PX may be electrically connected to two of the scan lines SL, one of the voltage lines VL, and one of the data lines DL. Each of the pixels PX may be defined as the minimum unit that outputs light.

The scan lines SL may provide the signals received from the scan driving controller 410 to the pixels PX. The scan lines SL may extend in the first direction (x-axis direction) and may be spaced apart from each other in the second direction (y-axis direction) intersecting the first direction (x-axis direction).

The data lines DL may supply the data voltages received from the display driver circuit 200 to the pixels PX. The data lines DL may extend in the second direction (y-axis direction) and may be spaced apart from each other in the first direction (x-axis direction).

The voltage lines VL may provide the supply voltage received from the display driver circuit 200 to the pixels PX through driving voltage lines VSL. The supply voltage may be at least one of a driving voltage, an initialization voltage, a reference voltage and a low-level voltage. The voltage lines VL may extend in the second direction (y-axis direction) and may be spaced apart from each other in the first direction (x-axis direction).

In the non-display area NDA, a scan driving controller 410, driving voltage lines VSL, fan-out lines FL, and a scan control line GCL may be disposed.

The scan driving controller 410 may receive a scan timing signal from the display driver circuit 200 and may generate scan signals in response to the scan timing signal to output the scan signals to the scan lines SL.

The fan-out lines FL may be extended from the display driver circuit 200 to the display area DA. The fan-out lines FL may provide the data voltages received from the display driver circuit 200 to the data lines DL. In other words, the display driver circuit 200 may output signals and voltages for driving the display panel 100 to the fan-out lines FL, and the display driver circuit 200 may provide the data voltage to the data lines DL through the fan-out line FL. Accordingly, the data voltages provided through the data lines DL may be applied to the pixels PX, so that the luminance of the pixels PX may be controlled.

The scan control line GCL may extend from the display driver circuit 200 to the scan driving controller 410. The scan control line GCL may provide the scan control signal received from the display driver circuit 200 to the scan driving controller 410.

The driving voltage line VSL may be electrically connected to the voltage lines VL, and the voltage can be more uniformly applied to the pixels PX of the display area DA by the voltage lines VL electrically connected to the driving voltage line VSL.

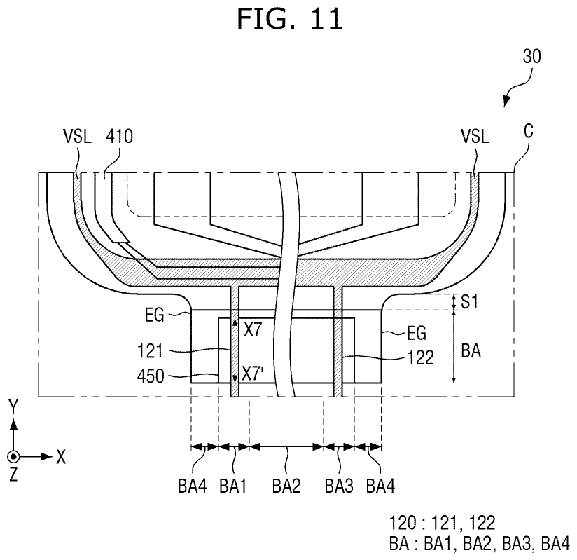

As described above, the signal lines 120 overlapping the bending area BA of the subsidiary area SBA can be protected by the bending protection layer 450 while they are bent. In addition, the bending protection layer 450 may determine a location of a neutral surface NS (see FIG. 11) of the bending area BA in case that the subsidiary area SBA of the display device 10 is bent.

Accordingly, the bending protection layer 450 can control the stress of the structure overlapping the bending area BA. By setting the thickness of the bending protection layer 450 so that the neutral surface may be close to the signal lines 120 disposed in the bending area BA, it may be possible to mitigate the stress due to bending in case that the signal lines 120 made of conductors are bent.

FIG. 7 is an enlarged plan view of area C of FIG. 5.

Referring to FIG. 7, one of the signal lines 120 that may be disposed closest to the edge EG of the second substrate 112 on one side in the first direction (x-axis direction) may be defined as a first outermost signal line 121. In addition, one of the signal lines 120 that may be disposed closest to the edge EG of the substrate on the opposite side in the first direction (x-axis direction) may be defined as a second outermost signal line 122.

For convenience of illustration, the driving voltage line VSL may be defined as the first outermost signal line 121 and the second outermost signal line 122 in the example shown in FIG. 7, but the disclosure may not be limited thereto. In other words, the first outermost signal line 121 and the second outermost signal line 122 may include all types of signal lines 120 as well as the driving voltage line VSL. For example, the first outermost signal line 121 and the second outermost signal line 122 may be scan lines SL, may be data lines DL, or may be any type of signal line 120 such as clock lines CLK and initialization lines INT.

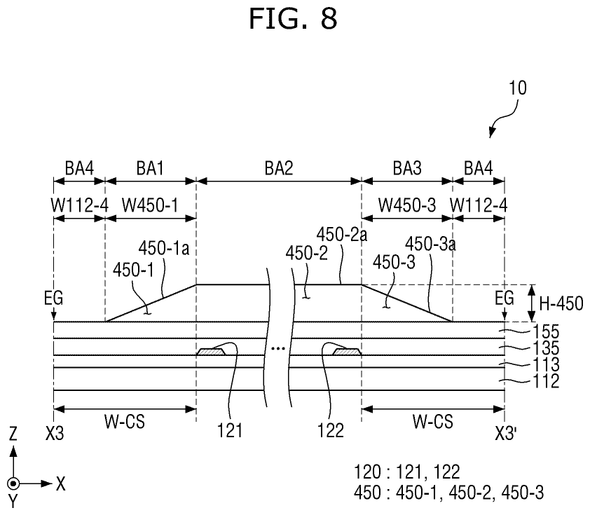

FIG. 8 is a schematic cross-sectional view of the bending area BA of the display device, taken along line X3-X3′ of FIG. 7.

Referring to FIG. 8, the schematic cross-sectional structure of the bending area BA will be described.

The bending area BA may include the second substrate 112, and the second substrate 112 may overlap the main area MA and the subsidiary area SBA.

As described above, the second substrate 112 may be made of an insulating material such as a polymer resin. For example, the second substrate 112 may include polyimide (PI). The second substrate 112 may be a flexible substrate that can be bent, folded, or rolled.

A barrier layer 113 may be disposed on the second substrate 112 to overlap the main area MA and the subsidiary area SBA. The barrier layer 113 can prevent permeation of moisture. The barrier layer 113 may be formed of multiple inorganic layers stacked on one another alternately. The barrier layer 113 may be made up of multiple layers in which one or more inorganic layers of silicon nitride, silicon oxynitride, silicon oxide, titanium oxide and aluminum oxide may be alternately stacked on one another.

The signal lines 120 may be disposed on the barrier layer 113. For convenience of illustration, only the first outermost signal line 121 and the second outermost signal line 122 disposed at opposing ends in the first direction (x-axis direction) among the signal lines 120 are shown. In practice, multiple signal lines 120 may be disposed.

An organic layer 135 may be disposed on the barrier layer 113 to overlap the main area MA and the subsidiary area SBA. The organic layer 135 may provide an approximately flat surface. The organic layer 135 may be formed of an organic layer such as acryl resin, epoxy resin, phenolic resin, polyamide resin, polyimide resin, or a combination thereof.

The pixel-defining layer 155 may be disposed on the organic layer 135 to overlap the main area MA and the subsidiary area SBA. The pixel-defining layer 155 may define emission areas of the pixels PX in the display area DA. The pixel-defining layer 155 may be formed of an organic layer such as acryl resin, epoxy resin, phenolic resin, polyamide resin, polyimide resin, or a combination thereof.

The bending protection layer 450 may be disposed on the pixel-defining layer 155. The bending protection layer 450 may be in contact with the pixel-defining layer 155 and may be spaced apart from the opposing edges EG of the second substrate 112 in the first direction (x-axis direction). As described above, the bending protection layer 450 can alleviate stress generated during bending.

The bending protection layer 450 may include a synthetic resin. For example, the bending protection layer 450 may include at least one of acrylonitrile butadiene styrene copolymer (ABS), urethane acrylate (UA), polyurethane (PU), polyethylene (PE), ethylene vinyl acetate (EVA), and polyvinyl chloride (PVC).

Referring to FIG. 8, the bending protection layer 450 may be divided into a first portion 450-1, a second portion 450-2, and a third portion 450-3 along the thickness shape in the third direction (z-axis direction).

In some embodiments, the first portion 450-1 of the bending protection layer 450 may be disposed at one side of the bending protection layer 450 in the first direction (x-axis direction), and may have the thickness H-450 of the bending protection layer 450 decreasing toward the edge EG of the second substrate 112 closest to the first portion 450-1 for reasons of processing. Accordingly, the first portion 450-1 of the bending protection layer 450 may include an inclined surface 450-1a inclined toward the edge EG of the second substrate 112 disposed closest to the first portion 450-1.

The width W450-1 of the first portion 450-1 of the bending protection layer 450 may range from about 800 μm to about 1,000 μm. The height H450 of the first portion 450-1 of the bending protection layer 450 may be greater than 0 μm and equal to or less than about 90 μm.

In other words, the inclined surface 450-1a of the first portion 450-1 of the bending protection layer 450 may have a thickness decreasing in the range of about 90 μm or less toward the edge EG of the substrate closest to the first portion 450-1.

In some embodiments, the third portion 450-3 of the bending protection layer 450 may be disposed on the opposite side of the bending protection layer 450 in the first direction (x-axis direction), and may have the thickness H-450 of the bending protection layer 450 decreasing toward the edge EG of the second substrate 112 closest to the third portion 450-3. Accordingly, the third portion 450-3 of the bending protection layer 450 may include an inclined surface 450-3a inclined toward the edge EG of the substrate disposed closest to the third portion 450-3.

The width W450-3 of the third portion 450-3 of the bending protection layer 450 may range from about 800 μm to about 1,000 μm. The height H450 of the third portion 450-3 of the bending protection layer 450 may be greater than about 0 μm and equal to or less than about 90 μm.

In other words, the inclined surface 450-3a of the third portion 450-3 of the bending protection layer 450 may have a thickness decreasing in the range of about 90 μm or less toward the edge EG of the substrate closest to the third portion 450-3.

In some embodiments, the second portion 450-2 of the bending protection layer 450 may be disposed at the center of the bending protection layer 450 between the first portion 450-1 and the third portion 450-3 of the bending protection layer 450, and may occupy most of the area of the bending protection layer 450. The second portion 450-2 of the bending protection layer 450 may include an approximately flat surface 450-2a extended from (or connected to) the inclined surface 450-1a of the first portion 450-1 and the inclined surface 450-3a of the third portion 450-3.

The thickness H-450 of the second portion 450-2 of the bending protection layer 450 may range from about 100 μm to about 120 μm.

In some embodiments, the signal lines 120 of the display device 10 may overlap the second portion 450-2 of the bending protection layer 450. In other words, among the signal lines 120, the first outermost signal line 121 and the second outermost signal line 122 may not overlap the first portion 450-1 or the third portion 450-3 of the bending protection layer 450, and may overlap only the second portion 450-2 of the bending protection layer 450.

In other words, the signal lines 120 including the first outermost signal line 121 and the second outermost signal line 122 may be disposed such that they overlap the second portion 450-2 of the bending protection layer 450 that includes the approximately flat surface 450-2a having a uniform thickness.

In some embodiments, a part of the bending area BA corresponding to the first portion 450-1 of the bending protection layer 450 may be defined as a first bending area BA1, a part of the bending area BA corresponding to the second portion 450-2 of the bending protection layer 450 may be defined as a second bending area BA2, and a part of the bending area BA corresponding to the third portion 450-3 of the bending protection layer 450 may be defined as a third bending area BA3. A part of the bending area BA not corresponding to any portion of the bending protection layer 450 may be defined as a fourth bending area BA4. For example, the width W112-4 of the second substrate 112 overlapping the fourth bending area BA4 may range from about 800 μm to about 1,000 μm. The first bending area BA1 and the third bending area BA3 may overlap the inclined surfaces 450-1a and 450-3a of the bending protection layer 450, respectively, and may not overlap any of the signal lines 120.

In some embodiments, the second bending area BA2 may overlap the approximately flat surface 450-2a of the bending protection layer 450 and correspond to the signal lines 120. The fourth bending area BA4 may be absent of the bending protection layer 450 as well as the signal lines 120.

In some embodiments, the distance (or width of an edge portion of the second substrate 112) W-CS in the first direction (x-axis direction) from the edge (or side edge) of the first outermost signal line 121 to the edge EG of the second substrate 112 closest to the edge of the first outermost signal line 121 may be equal to or greater than about 1,800 μm. For example, the width W450-1 of the first portion 450-1 of the bending protection layer 450 of the display device 10 may include a value of about 800 μm to about 1,000 μm, the width W112-4 of the second substrate 112 overlapping the fourth bending area BA4 may include a value of about 800 μm to about 1,000 μm, and the distance W-CS in the first direction from the edge EG of the second substrate 112 disposed closest to the first outermost signal line 121 and a nearest edge of the first outermost signal line 121 may be about 1,800 μm or more.

In some embodiments, the distance W-CS in the first direction (x-axis direction) from the edge (or side edge) of the second outermost signal line 122 to the edge EG of the second substrate 112 closest to the second outermost signal line 122 may be equal to or greater than about 1,800 μm. In other words, the width W450-3 of the third portion 450-3 of the bending protection layer 450 of the display device 10 may include a value of about 800 μm to about 1,000 μm, the width W112-4 of the second substrate 112 overlapping the fourth bending area BA4 may include a value of about 800 μm to about 1,000 μm, and the distance W-CS in the first direction (or x-axis direction) from the edge EG of the second substrate 112 disposed closest to the second outermost signal line 122 to a nearest side edge of the second outermost signal line 122 may be about 1,800 μm or more.

Although the drawings illustrate for convenience that the first outermost signal line 121 and the second outermost signal line 122 may be disposed at opposing ends of the second bending area BA2 and be disposed close to the first bending area BA1 and the third bending area BA3, respectively, the disclosure may not be limited thereto. In other words, the first outermost signal line 121 and the second outermost signal line 122 may be disposed at any location in the second portion 450-2 where the bending protection layer 450 includes the approximately flat surface 450-2a and may be disposed at the opposing ends of the signal lines 120.

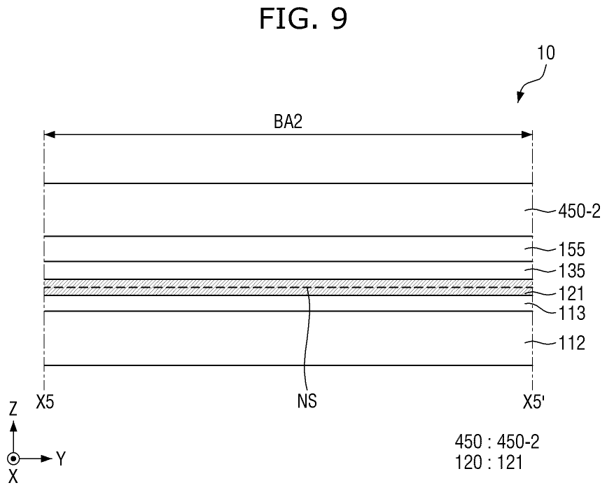

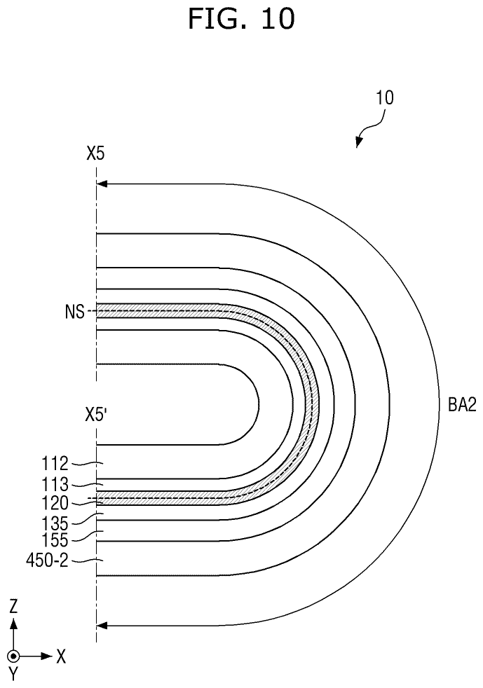

FIG. 9 is a schematic cross-sectional view of an outermost signal line of the display device, taken along line X5-X5′ of FIG. 7. FIG. 10 is a schematic cross-sectional view of the first outermost signal line of FIG. 9 in case that the outermost signal line is bent.

Referring to FIGS. 9 and 10, the first outermost signal line 121 overlapping with the second bending area BA2 may be disposed on the barrier layer 113. The organic layer 135 may be disposed on the first outermost signal line 121, and the pixel-defining layer 155 may be disposed on the organic layer 135.

In some embodiments, a surface that does not deform in case that the display device 10 is folded with a curvature may be defined as a neutral surface NS. The surface that does not deform implies a surface with no expansion or contraction, and thus the bending stress applied to the neutral surface NS may be zero.

In some embodiments, the first outermost signal line 121 may overlap the second portion 450-2 of the bending protection layer 450. As described above, the thickness H450 of the second portion 450-2 of the bending protection layer 450 includes the range of about 100 μm to about 120 μm, and the first outermost signal line 121 overlapping the second portion 450-2 may include the neutral surface NS near the layer where the first outermost signal line 121 may be disposed. Accordingly, the bending stress applied to the signal lines 120 may be zero, and it may be possible to avoid cracks in the signal lines 120 caused in case that the display device 10 is bent. In addition, it may be possible to improve poor visibility issue of the display device 10.

Although the neutral surface NS of the display device 10 overlaps the first outermost signal line 121 in FIGS. 9 and 10, the disclosure may not be limited thereto. For example, the neutral surface NS may be moved as the thickness and modulus of each element forming the display device may be changed.

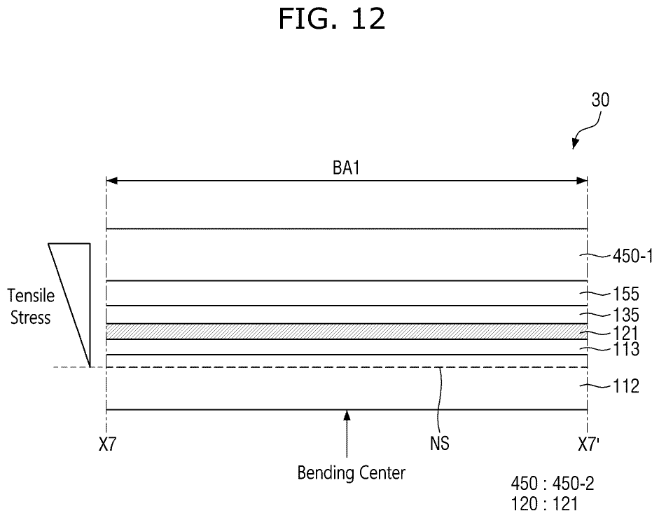

FIG. 11 is an enlarged plan view of area C of FIG. 5 as a Comparative Example. FIG. 12 is a schematic cross-sectional view of the display device 30, taken along line X7-X7′ of FIG. 11.

A display device 30 of FIGS. 11 and 12 may be different from the display device 10 in that signal lines 120, including a first outermost signal line 121 and a second outermost signal line 122, may be disposed in the first portion 450-1 and the third portion 450-3 of the bending protection layer 450. For example, the display device 30 in which the signal lines 120 may be disposed in the bending area BA where the bending protection layer 450 has different thicknesses may have a neutral surface NS different from that of the display device 10.

As shown in FIG. 12, the bending protection layer 450 overlapping the first outermost signal line 121 of the display device 30 may include the first portion 450-1 having a range greater than about 0 μm and equal to or less than about 90 μm. Therefore, during bending, the location of the neutral surface NS having the bending stress of zero may be moved toward the lower surface that becomes the center of bending, and accordingly, the layer where the signal lines 120 may be disposed are spaced apart from the neutral surface NS and therefore are subjected to significant bending stress. For example, the upper portions of the bending protection layer 450 disposed above the neutral surface NS may have greater tensile stress as it moves away from the neutral surface NS with respect to the bending center. In the drawing, the magnitude of tensile stress, which increases with the distance from the neutral surface NS, may be expressed as the side of a triangle.

Therefore, in case that the signal lines 120, including the first outermost signal line 121 and the second outermost signal line 122 of the display device 30, are bent, a crack may occur in the signal lines 120. If a crack occurs in the signal lines 120, no signal may be applied to the pixels PX of the display area DA, which may cause visibility defects in the display device 10.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a first substrate comprising a first area, a second area and a bending area between the first area and the second area;
a display element layer disposed on the first area of the first substrate;
a plurality of signal lines disposed on the bending area of the first substrate, the plurality of signal lines being spaced apart from one another in a first direction and being electrically connected to the display element layer; and
a bending protection layer disposed on the bending area of the first substrate and covering the plurality of signal lines, wherein the bending protection layer comprises:
a first portion that does not overlap the plurality of signal lines, the first portion having an inclined surface along the first direction; and
a second portion that overlaps plurality of the signal lines, the second portion extending to the first portion along the first direction, and having an approximately flat surface, and
wherein the plurality of signal lines include a first outermost signal line at an outermost position among the plurality of signal lines in the first direction, and the first outermost signal line overlaps the second portion of the bending protection layer.

2. The display device of claim 1, wherein
the bending protection layer further comprises a third portion disposed on an opposite side in the first direction from the first portion, the second portion being disposed between the first portion and the third portion, the third portion including an inclined surface,
the plurality of signal lines further comprise a second outermost signal line at an outermost location among the plurality of signal lines in the first direction and disposed at an opposite side from the first outermost signal line, and
the second outermost signal line overlaps the second portion.

3. The display device of claim 2, wherein
the inclined surface of the first portion of the bending protection layer, the approximately flat surface of the second portion, and the inclined surface of the third portion are contiguous, and
a thickness of the second portion of the bending protection layer in a direction perpendicular to the first direction is greater than thicknesses of the first and third portions of the bending protection layer.

4. The display device of claim 3, wherein the first outermost signal line and the second outermost signal line overlap neither the first portion nor the third portion of the bending protection layer.

5. The display device of claim 4, wherein the thickness of the second portion of the bending protection layer is greater than about 90 μm and equal to or less than about 120 μm.

6. The display device of claim 3, wherein the inclined surface of the first portion and the inclined surface of the third portion of the bending protection layer are inclined toward respective edges of the first substrate disposed adjacent thereto.

7. The display device of claim 6, wherein the thickness of the first portion and the thickness of the third portion of the bending protection layer are greater than about 0 μm and equal to or less than about 90 μm.

8. The display device of claim 6, wherein widths of the first portion and the third portion of the bending protection layer in the first direction are equal to or greater than about 800 μm and equal to or less than about 1,000 μm.

9. The display device of claim 1, wherein
the bending area of the first substrate comprises an edge portion not overlapping the bending protection layer,
the edge portion of the bending area of the first substrate comprises edges of the first substrate at opposing sides in the first direction, and
a width of the edge portion of the bending area of the first substrate in the first direction is in a range of about 800 μm to about 1,000 μm.

10. The display device of claim 8, wherein a distance in the first direction from a nearest one of the respective edges of the first substrate to a side edge of the first outermost signal line is equal to or greater than about 1,800 μm.

11. The display device of claim 1, further comprising:
a second substrate disposed on the first substrate, the first substrate being disposed between the display element layer and the second substrate, wherein
the second substrate comprises:
a (2-1)-th substrate overlapping the first area of the first substrate; and
a (2-2)-th substrate overlapping the second area of the first substrate,
the bending protection layer partially overlaps the second substrate, and
the (2-1)-th substrate and the (2-2)-th substrate are spaced apart from each other.

12. The display device of claim 11, wherein the second substrate does not overlap the bending area.

13. The display device of claim 12, wherein
a surface of the second substrate facing away from the first substrate comprises inclined surfaces at opposing ends, and
at least one of the inclined surfaces overlap the bending protection layer.

14. A display device comprising:
a substrate comprising a first area, a second area and a bending area between the first area and the second area;
a display element layer disposed on the first area of the substrate;
a plurality of signal lines disposed on the bending area of the substrate, the plurality of signal lines being spaced apart from one another in a first direction, and the plurality of signal lines being electrically connected to the display element layer; and
a bending protection layer disposed on the bending area of the substrate and covering the plurality of signal lines, wherein
the plurality of signal lines comprise a first outermost signal line at an outermost location in the first direction among the plurality of signal lines, and
the bending protection layer includes a first end that is disposed between a first edge of the substrate and the first outermost signal line.

15. The display device of claim 14, wherein
the plurality of signal lines further comprise a second outermost signal line disposed at an outermost location in the first direction among the plurality of signal lines, the second outermost signal line being disposed on an opposite side from the first outermost signal line, and
the bending protection layer includes a second end that is disposed between a second edge of the substrate and the second outermost signal line.

16. The display device of claim 15, wherein a thickness of the bending protection layer overlapping the plurality of signal lines in a direction perpendicular to the first direction is greater than about 90 μm and equal to or less than about 120 μm.

17. The display device of claim 16, wherein a distance between the first edge of the substrate and an edge of the first outermost signal line facing the first end of the bending protection layer, and a distance between the second edge of the substrate and an edge of the second outermost signal line facing the second end of the bending protection layer are greater than about 1,800 μm.

18. The display device of claim 17, wherein a distance in the first direction from the first edge of the substrate to the first end of the bending protection layer is in a range of about 800 μm to about 1,000 μm.

19. The display device of claim 17, wherein a distance in the first direction between the first end of the bending protection layer and the edge of the first outermost signal line facing the first end of the bending protection layer, and a distance in the first direction between the second end of the bending protection layer and the edge of the second outermost signal line facing the second end of the bending protection layer are in a range of about 800 μm to about 1,000 μm.

20. The display device of claim 15, wherein the plurality of signal lines are not disposed between the edges of the substrate and the ends of the bending protection layer.
